(19) United States
(12) Patent Application Publication
(10) Pub. No.: US 2025/0380486 A1
(43) Pub. Date: Dec. 11, 2025

(54) SEMICONDUCTOR DEVICE, METHOD OF MANUFACTURING SEMICONDUCTOR DEVICE, AND ELECTRONIC APPARATUS

(71) Applicant: INSTITUTE OF MICROELECTRONICS, CHINESE ACADEMY OF SCIENCES, Beijing (CN)

(72) Inventors: Qingzhu ZHANG, Beijing (CN); Renjie JIANG, Beijing (CN); Guanqiao SANG, Beijing (CN); Lei CAO, Beijing (CN); Lianlian LI, Beijing (CN); Meihe ZHANG, Beijing (CN)

(21) Appl. No.: 18/984,737

(22) Filed: Dec. 17, 2024

(30) Foreign Application Priority Data
Jun. 11, 2024 (CN) 202410749518.9

(51) Int. Cl. H10D 64/66; H10D 30/00; H10D 30/01; H10D 62/10; H10D 64/01

(52) U.S. Cl. CPC H10D 64/675; H10D 30/0191; H10D 30/502; H10D 62/121; H10D 64/017; H10D 64/021

(57) ABSTRACT

The present disclosure provides a semiconductor device, a method, and an electronic apparatus. The device includes: a substrate; a channel layer stacking portion including multiple channel layers along a thickness direction of the substrate, a length direction of the channel layer is perpendicular to the thickness direction of the substrate, and the channel layer includes a first end, a middle section and a second end along the length direction; a gate-all-around surrounding the middle section; a source/drain functional portion; and a spacer structure including first and second spacers. The first spacer is between first ends and second ends of adjacent channel layers, and includes a cavity. The second spacer is on a side of the channel layer stacking portion away from the substrate and on both sides of the gate-all-around along the length direction. A dielectric constant of the first spacer is greater than that of the second spacer.

### CROSS REFERENCE TO RELATED APPLICATION

This application claims priority to Chinese Patent Application No. 202410749518.9, filed on Jun. 11, 2024, the entire content of which is incorporated herein in its entirety by reference.

### TECHNICAL FIELD

The present disclosure relates to the field of semiconductor technology, in particular to a semiconductor device, a method of manufacturing a semiconductor device, and an electronic apparatus.

### BACKGROUND

As the feature size of integrated circuits is decreased constantly, nano gate-all-around field effect transistors (GAA-FETs) have become the next-generation key structure for achieving size miniaturization. A channel of the nano gate-all-around field effect transistor is mainly a stacked nanosheet structure. The nano gate-all-around field effect transistors have advantages of a good gate control and a large driving current per unit projection area. However, the parasitic capacitance between the gate and the source/drain is large, which will significantly reduce the operation speed of the circuit.

### SUMMARY

In a first aspect of the present disclosure, a semiconductor device is provided, including:
a substrate;
a channel layer stacking portion formed on a side of the substrate, where the channel layer stacking portion includes a plurality of channel layers arranged along a thickness direction of the substrate, a length direction of the channel layer is perpendicular to the thickness direction of the substrate, and each of the plurality of channel layers includes a first end, a middle section and a second end arranged along the length direction of the channel layer;
a gate-all-around surrounding the middle section of the channel layer with respect to the length direction of the channel layer;
a source/drain functional portion including a source portion and a drain portion, where the source portion and the drain portion are located on two opposite sides of the channel layer stacking portion along the length direction of the channel layer; and
a spacer structure configured to isolate the source/drain functional portion from the gate-all-around, where the spacer structure includes a first spacer and a second spacer, the first spacer is located between first ends of adjacent channel layers and between second ends of the adjacent channel layers, the first spacer includes a cavity, the second spacer is located on a side of the channel layer stacking portion away from the substrate and on both sides of the gate-all-around along the length direction of the channel layer, and a dielectric constant of a material of the first spacer is greater than a dielectric constant of a material of the second spacer.

In a second aspect of the present disclosure, a method of manufacturing a semiconductor device is provided, including:
providing a substrate;
forming a stack epitaxy structure on a side of the substrate, and thinning a preset region in the stack epitaxy structure on two sides along a first direction, so as to form a thinned region and a reserved region, where the stack epitaxy structure includes a plurality of channel formation layers and a plurality of sacrificial layers alternately arranged in a direction away from the substrate;
forming a dummy gate covering two side surfaces of the thinned region along a second direction and covering a surface of the thinned region on a side of the thinned region away from the substrate, where a preset gap is formed between the dummy gate and the reserved region, and the second direction is perpendicular to each of the first direction and a thickness direction of the substrate;
removing a portion of the sacrificial layer corresponding to the preset gap to form a hollow portion;
forming a first spacer including a cavity in the hollow portion;
forming a second spacer material layer on a side of the stack epitaxy structure and the dummy gate away from the substrate;
patterning the second spacer material layer to form a second spacer, including: removing a portion of the second spacer material layer located on a side of the dummy gate away from the substrate to form the second spacer, so as to form a spacer structure including the first spacer and the second spacer;
patterning the reserved region such that a size of the reserved region along the second direction is a preset size, so as to pattern the channel formation layer to form a channel layer, and then form a channel layer stacking portion including a plurality of channel layers arranged along the thickness direction of the substrate, where a length direction of the channel layer is perpendicular to the thickness direction of the substrate, and each of the plurality of channel layers includes a first end, a middle section and a second end arranged along the length direction of the channel layer;
removing the dummy gate to expose a portion of the sacrificial layer corresponding to the thinned region, and removing the portion of the sacrificial layer corresponding to the thinned region;
forming a gate-all-around surrounding the middle section of the channel layer with respect to the length direction of the channel layer, where the first spacer is in contact with the gate-all-around; and
forming a source/drain functional portion including a source portion and a drain portion, where the source portion and the drain portion are located on two opposite sides of the channel layer stacking portion along the length direction of the channel layer, and the source/drain functional portion is isolated from the gate-all-around by the spacer structure.

In a third aspect of the present disclosure, an electronic apparatus is provided, including at least one semiconductor device provided in the first aspect, and/or at least one semiconductor device manufactured by using the method provided in the second aspect.

### BRIEF DESCRIPTION OF THE DRAWINGS

Through the following detailed description of the preferred embodiments, those of ordinary skill in the art will understand various additional advantages and benefits of the present disclosure. The drawings are only for illustrating the preferred embodiments and are not intended to limit the present disclosure. Also, throughout the drawings, the same reference numerals are used to denote the same components. In the drawings:

FIG. 1 is a schematic diagram of a structure of a semiconductor device provided in an embodiment of the present disclosure;

FIG. 2 is an enlarged view of Q region in FIG. 1;

FIG. 3 is a cross-sectional view along line M-M′ in FIG. 1;

FIG. 4 is a schematic diagram of a structure of another semiconductor device provided in an embodiment of the present disclosure;

FIG. 5 is a flowchart of a method of manufacturing a semiconductor device provided in an embodiment of the present disclosure;

FIG. 6 is a schematic diagram of layers corresponding to a method of manufacturing a semiconductor device provided in an embodiment of the present disclosure;

FIG. 7 is a schematic diagram of a structure corresponding to a method of manufacturing a semiconductor device provided in an embodiment of the present disclosure;

FIGS. 8 to 11 are schematic diagrams of structural changes of layers corresponding to a method of manufacturing a semiconductor device provided in an embodiment of the present disclosure;

FIG. 12 is an enlarged view of P region in FIG. 11; and

FIGS. 13 to 17 are schematic diagrams of structural changes of layers corresponding to a method of manufacturing a semiconductor device provided in an embodiment of the present disclosure.

### REFERENCE NUMERALS

1: semiconductor device; 11: substrate; 12: channel layer stacking portion; 121: channel layer; 1211: first end; 1212: middle section; 1213: second end; 13: gate-all-around; 14: source/drain functional portion; 15: spacer structure; 151: first spacer; 1511: cavity; 152: second spacer; 153: third spacer; 154: fourth spacer; 16: stack epitaxy structure; 161: channel formation layer; 162: sacrificial layer; A1: thinned region; A2: reserved region; 17: dummy gate; L: preset gap; 18: hollow portion; 19: second spacer material layer; 20: trench isolation layer.

### DETAILED DESCRIPTION OF EMBODIMENTS

Exemplary embodiments of the present disclosure will be described below in more detail with reference to the accompanying drawings. Although the exemplary embodiments of the present disclosure are shown in the drawings, it should be understood that the present disclosure may be implemented in various ways and should not be limited to the embodiments set forth herein. On the contrary, these embodiments are provided to enable a more thorough understanding of the present disclosure and to fully introduce the scope of the present disclosure to those skilled in the art.

It should be understood that terms used herein are for describing particular exemplary embodiments only and are not intended to limit the present disclosure. As used herein, the singular forms “a”, “an” and “the” may be intended to include the plural forms as well, unless the context clearly indicates otherwise. The terms “comprising,” “including,” “containing,” and “having” are inclusive, and thus specify the presence of stated features, steps, operations, elements, and/or components, but do not exclude the presence or addition of one or more other features, steps, operations, elements, components, and/or combinations thereof. The method steps, processes, and operations described herein are not to be construed as necessarily requiring their performance in the particular order described or illustrated, unless specifically identified as an order of performance. It should be understood that additional or alternative steps may be employed.

Although the terms “first”, “second”, “third”, etc. may be used herein to describe various elements, components, regions, layers and/or sections, these elements, components, regions, layers and/or sections should not be limited by these terms. These terms may be only used to distinguish one element, component, region, layer or section from another element, component, region, layer or section. Terms such as “first”, “second”, and other numerical terms when used herein do not imply a sequence or order unless clearly indicated by the context. Therefore, a first element, component, region, layer or section discussed below could be termed a second element, component, region, layer or section without departing from the teachings of exemplary embodiments.

For ease of description, spatial relative relationship terms may be used in the present disclosure to describe the relationship of one element or feature relative to another element or feature as shown in the figures. These relative relationship terms are, for example, “internal”, “external”, “inside”, “outside”, “under”, “below”, “on”, “above”, etc. The spatially relative relationship terms are intended to encompass different orientations of the device in use or operation in addition to the orientation depicted in the figures. For example, if a device in a figure is turned over, elements described as “under” or “below” other elements or features would then be oriented “on” or “above” the other elements or features. Therefore, the example term “below” may include both an orientation of above and below. The device may be otherwise oriented (rotated by 90 degrees or at other orientations) and the spatially relative relationship descriptors used herein may interpret accordingly.

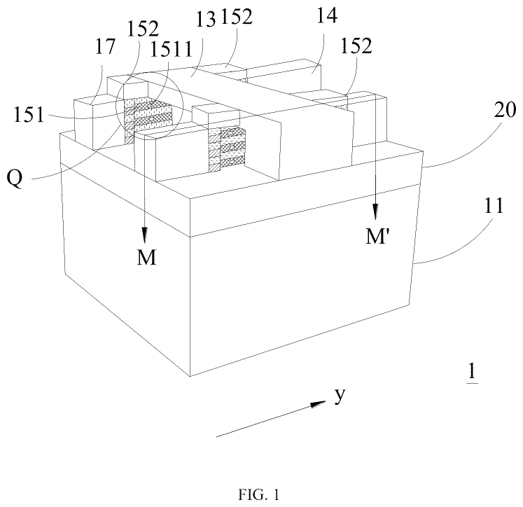

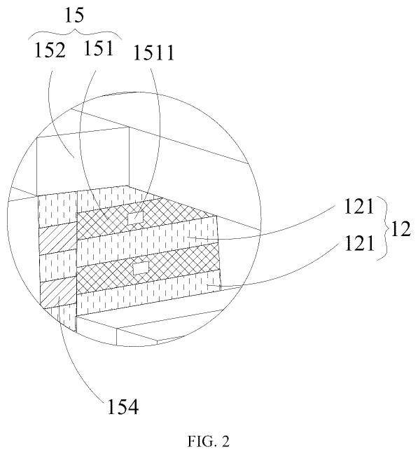

As shown in FIG. 1 to FIG. 3, according to an embodiment of the present disclosure, a semiconductor device 1 is proposed, including a substrate 11, a channel layer stacking portion 12, a gate-all-around 13, a source/drain functional portion 14, and a spacer structure 15. The channel layer stacking portion 12 is formed on a side of the substrate 11, and includes a plurality of channel layers 121 arranged along a thickness direction of the substrate 11. A length direction of the channel layer 121 is perpendicular to the thickness direction of the substrate 11. The channel layer 121 includes a first end 1211, a middle section 1212 and a second end 1213 that are arranged along the length direction. The gate-all-around 13 surrounds the middle section 1212 with respect to the length direction of the channel layer 121. The source/drain functional portion 14 includes a source portion and a drain portion, and the source portion and the drain portion are located at two opposite sides of the channel layer stacking portion 12 along the length direction. The spacer structure 15 is used for isolating the source/drain functional portion 14 from the gate-all-around 13. The spacer structure 15 includes a first spacer 151 and a second spacer 152. The first spacer 151 is located between first ends 1211 of the adjacent channel layers 121 and between second ends 1213 of adjacent channel layers 121, and the first spacer 151 includes a cavity 1511. The second spacer 152 is located on a side of the channel layer stacking portion 12 away from the substrate 11, and is located on both sides of the gate-all-around 13 along the length direction. A dielectric constant of a material of the first spacer 151 is greater than a dielectric constant of a material of the second spacer 152.

The semiconductor device 1 provided in the present disclosure includes the substrate 11, the channel layer stacking portion 12, the gate-all-around 13, the source/drain functional portion 14 and the spacer structure 15. The channel layer stacking portion 12 is formed on a side of the substrate 11 and includes the plurality of channel layers 121 arranged along the thickness direction of the substrate 11. The length direction of the channel layer 121 is perpendicular to the thickness direction of the substrate 11. The channel layer 121 includes the first end 1211, the middle section 1212 and the second end 1213 which are arranged along the length direction. The gate-all-around 13 surrounds the middle section 1212 with respect to the length direction of the channel layer 121, so that the gate-all-around 13 may be in fully contact with a circumferential surface of the channel layer 121 with respect to the length direction of the channel layer 121, so as to suppress a current and improve the performance of the semiconductor device 1. The source/drain functional portion 14 includes the source portion and the drain portion, and the source portion and the drain portion are located at the two opposite sides of the channel layer stacking portion 12 along the length direction. The first spacer 151 is located between the first ends 1211 of adjacent channel layers 121 and between the second ends 1213 of adjacent channel layers 121. The first spacer 151 includes the cavity 1511. The second spacer 152 is located on the side of the channel layer stacking portion 12 away from the substrate 11, and is located on both sides of the gate-all-around 13 along the length direction. The dielectric constant of the material of the first spacer 151 is greater than the dielectric constant of the material of the second spacer 152. The dielectric constant of the first spacer 151 may be reduced by forming the cavity 1511 in the first spacer 151, thereby reducing the parasitic capacitance between the first spacer 151 and the gate-all-around 13 to improve the operation speed of the semiconductor device 1. In addition, the first spacer 151 is made of a material with a high dielectric constant, which may enhance the electric field coupling effect of the gate-all-around 13 on the first spacer 151, reduce the resistance of the first spacer 151 and improve the driving performance. That is, the first spacer 151, which is made of the material with a high dielectric constant, surrounds the cavity 1511 which is connected to the external air and has a low dielectric constant, so that the performance of the first spacer 151 may be comprehensively improved. In this way, the parasitic capacitance and the driving performance may be both taken into account. Furthermore, the second spacer 152 is made of the material with a low dielectric constant, which may reduce the parasitic capacitance. In the semiconductor device 1 provided in the present disclosure, the first spacer 151 made of the material with a high dielectric constant is provided to surround the cavity 1511 with a low dielectric constant, and the second spacer 152 with a low dielectric constant is provided, thereby achieving the isolation of the source/drain functional portion 14 from the gate-all-around 13, and taking into account both the parasitic capacitance and the driving performance.

Specifically, the substrate 11 may be any substrate known to those skilled in the art for supporting the semiconductor device 1, such as a silicon-on-insulator (SOI) substrate, a bulk silicon substrate, a silicon carbide substrate, a germanium substrate, a silicon germanium substrate, a gallium arsenide substrate or a germanium-on-insulator substrate. The substrate 11 may also be a stack structure formed of a plurality of semiconductor material layers.

Specifically, in the above embodiment, the second spacer 152 may be in direct contact with the gate-all-around 13 and the source/drain functional portion 14. The second spacer 152 is made of the material with a low dielectric constant, which may be conducive to reducing the parasitic capacitance between the gate-all-around 13 and the source/drain functional portion 14 and increasing the operation frequency of the circuit.

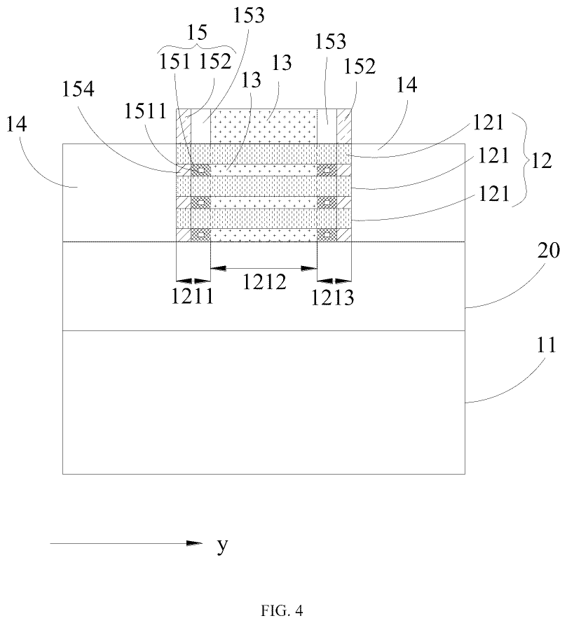

In a possible embodiment, as shown in FIG. 4, the spacer structure 15 further includes a third spacer 153 formed between the second spacer 152 and the gate-all-around 13. A material of the third spacer 153 is identical to the material of the first spacer 151.

In the above embodiment, the spacer structure 15 further includes the third spacer 153 formed between the second spacer 152 and the gate-all-around 13, so as to isolate the second spacer 152 from the gate-all-around 13, and further isolate the gate-all-around 13 from the source/drain functional portion 14. During the process of preparing the first spacer 151, while the material layer used to form the first spacer 151 forms the first spacer 151, a part of this material layer may form the third spacer 153. Therefore, the third spacer 153 is made of the same material as the first spacer 151. In addition, retaining the third spacer 153 may simplify the preparation process and omit a step of etching the material layer used to form the first spacer 151 to remove the part used to form the third spacer 153, thereby saving on preparation cost.

In a possible embodiment, as shown in FIG. 4, the spacer structure 15 further includes a fourth spacer 154. The fourth spacer 154 is formed between the first spacer 151 and the source/drain functional portion 14. The fourth spacer 154 is located between the first ends 1211 of adjacent channel layers 121 and between the second ends 1213 of adjacent channel layers 121.

In the above embodiment, the spacer structure 15 further includes the fourth spacer 154. The fourth spacer 154 is in direct contact with the source/drain functional portion 14 and may be made of a material with the same or similar crystal orientation as the source/drain functional portion 14. In this way, a dislocation problem of the source/drain functional portion 14 may be improved. In addition, it is possible to prevent damage caused by the injection of the source/drain functional portion 14, thereby reducing a contact resistance of the source/drain functional portion 14 and increasing an on-state current and a switching ratio. As such, the driving performance of the semiconductor device 1 may be improved, so as to achieve a high-performance semiconductor device 1.

In a possible embodiment, as shown in FIG. 4, an orthographic projection of the second spacer 152 on the substrate 11 covers an orthographic projection of the fourth spacer 154 on the substrate 11.

In the above embodiment, during the preparation process, the second spacer 152 may be prepared before the preparation of the fourth spacer 154. The second spacer 152 may be reused as an etching block layer in the patterning of the fourth spacer 154, so as to simplify the preparation process.

In a possible embodiment, a thickness of a sidewall of the first spacer 151 is in a range of 0.5 nm to 5 nm.

In the above embodiment, the thickness of the sidewall of the first spacer 151 may be 0.5 nm, 1.5 nm, 2.2 nm, 3.8 nm, 4.0 nm, 4.7 nm, 5 nm, etc.

The thickness of the first spacer 151 is set within the above range. In this way, on the one hand, it is possible to prevent a weak electric field coupling of the gate-all-around 13 to the first spacer 151 due to a too small thickness of the first spacer 151, thereby avoiding the large resistance of the first spacer 151 and the low driving performance; on the other hand, it is possible to prevent a failure in the formation of the cavity 1511 due to a too large thickness of the first spacer 151.

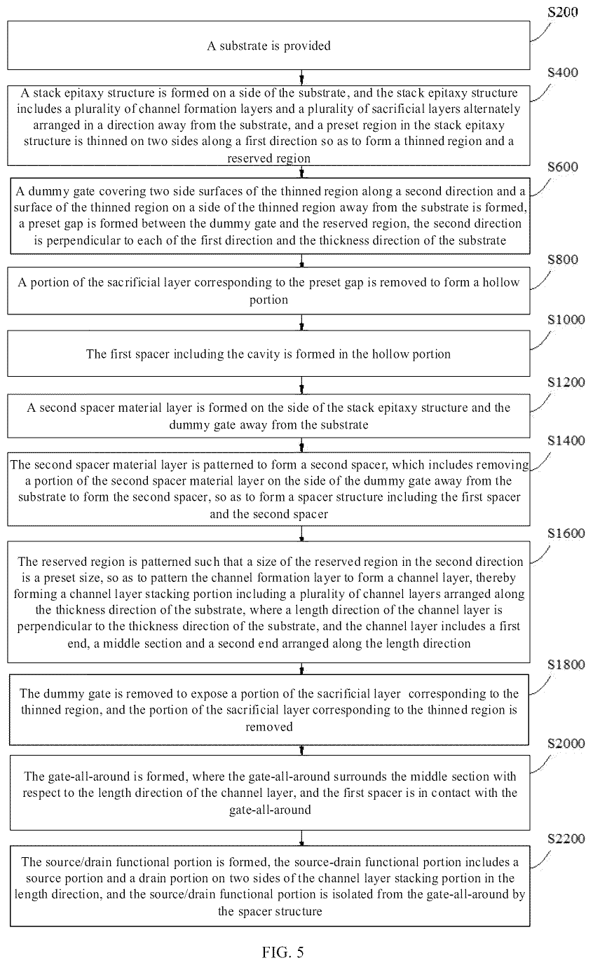

The present disclosure further provides a method of manufacturing the semiconductor device 1, as shown in FIG. 5, including the following steps S200 to S2200.

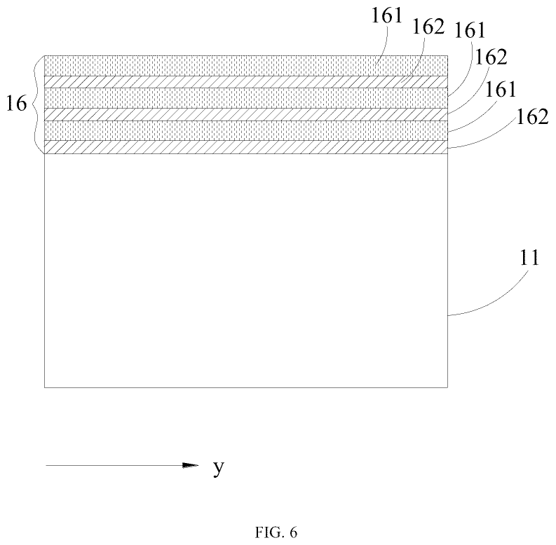

In S200, as shown in FIG. 6, a substrate 11 is provided.

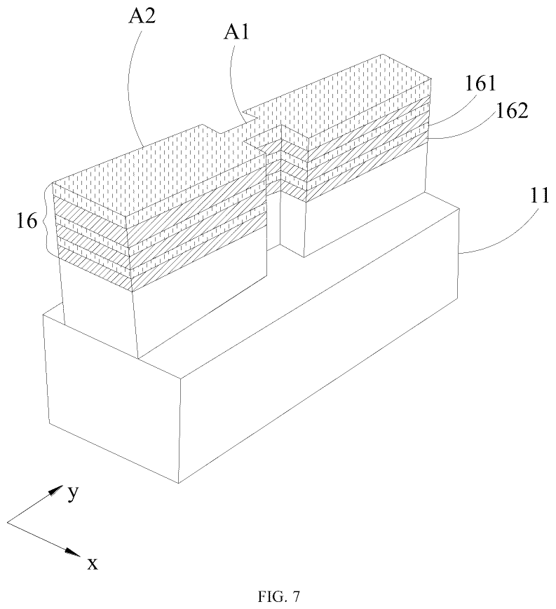

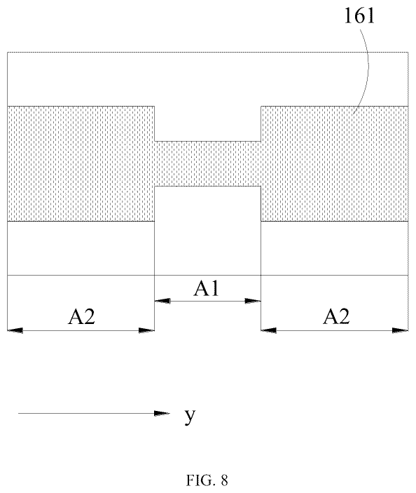

In S400, as shown in FIG. 6, a stack epitaxy structure 16 is formed on a side of the substrate 11, and the stack epitaxy structure 16 includes a plurality of channel formation layers 161 and a plurality of sacrificial layers 162 alternately arranged in a direction away from the substrate 11. As shown in FIGS. 7 and 8, a preset region in the stack epitaxy structure 16 is thinned on both sides along a first direction x, so as to form a thinned region A1 and a reserved region A2.

Specifically, a material of the channel formation layer 161 may include silicon; and a material of the sacrificial layer 162 may include silicon germanium. The preset region is used to form a gate-all-around 13 and a first spacer 151.

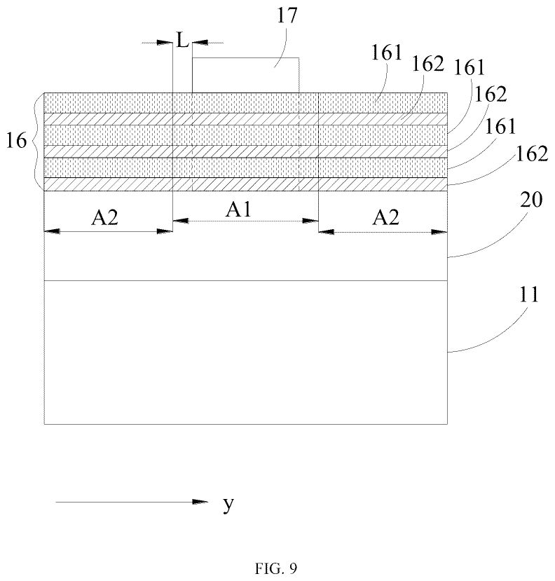

In S600, as shown in FIG. 9, a dummy gate 17 is formed, and the dummy gate 17 covers two side surfaces of the thinned region Al along a second direction y and also covers a surface of the thinned region A1 on a side of the thinned region A1 away from the substrate 11. A preset gap L is formed between the dummy gate 17 and the reserved region A2, and the second direction y is perpendicular to each of the first direction x and the thickness direction of the substrate 11.

Specifically, the dummy gate 17 is formed in the thinned region A1. The preset gap L is formed between the dummy gate 17 and each of the reserved regions A2 on both sides. The preset gap L is used to form the first spacer 151.

Specifically, a size of the preset gap L along the second direction y may be in a range of 3 nm to 20 nm.

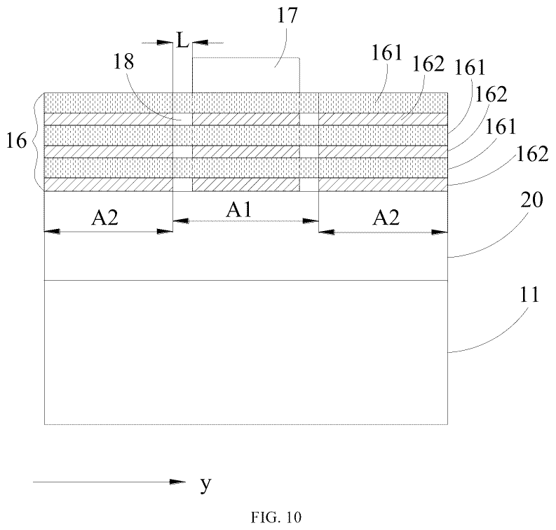

In S800, as shown in FIG. 10, a portion of the sacrificial layer 162 corresponding to the preset gap L is removed to form a hollow portion 18.

Specifically, a dry etching method or a wet etching method may be used to remove the portion of the sacrificial layer 162 corresponding to the preset gap L. Such manufacturing method is simple and has a high yield. Compared with the manufacturing method in the related art in which the sacrificial layer 162 would be etched in the second direction y and filling of other isolation medium would be performed, etching is performed in the first direction x in the above embodiment, which may achieve a high etching yield and be less likely to cause over-etching or under-etching, so that an impact on sizes of the dummy gate 17 and the isolation medium may be reduced.

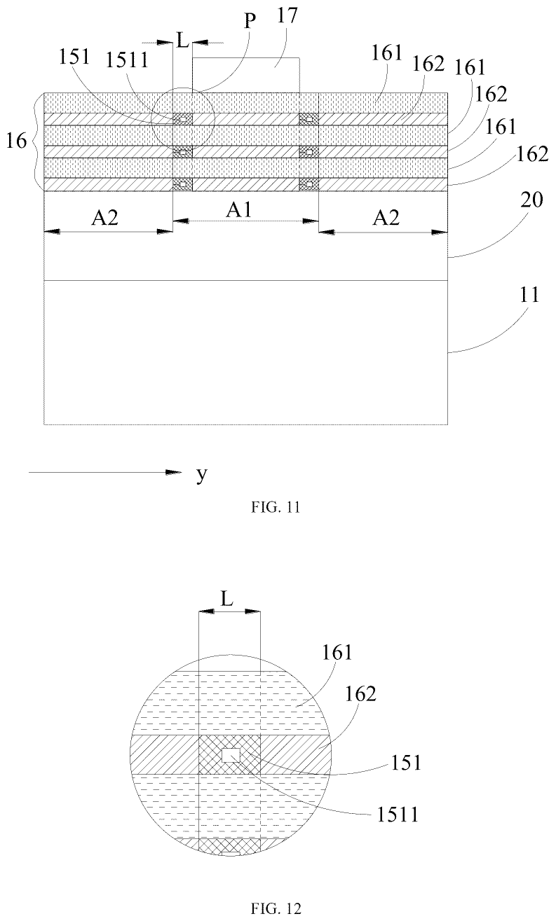

In S1000, as shown in FIGS. 11 and 12, the first spacer 151 including the cavity 1511 is formed in the hollow portion 18.

Specifically, a material layer with a good filling property and a high dielectric constant may be deposited using an atomic layer deposition (ALD) process. A thickness of the material layer, namely the thickness of the sidewall of the first spacer 151, may be in a range of 0.5 nm to 5 nm. In this way, on the one hand, it is possible to prevent a weak electric field coupling of the gate-all-around 13 to the first spacer 151 due to a too small thickness of the first spacer 151, thereby avoiding the large resistance of the first spacer 151 and the low driving performance; on the other hand, it is possible to prevent a failure in the formation of the cavity 1511 due to a too large thickness of the first spacer 151.

Specifically, when the material layer is deposited in the hollow portion 18 using the atomic layer deposition (ALD) process, the cavity 1511 may be naturally formed by controlling the deposition amount of the material.

Specifically, in the process of depositing the above-mentioned material layer used to form the first spacer 151, it is prone to simultaneously deposit the above-mentioned material layer used to form the first spacer 151 on a side of the stack epitaxy structure 16 and the dummy gate 17 away from the substrate 11. A portion of the above-mentioned material layer used to form the first spacer 151, which is located on the side of the stack epitaxy structure 16 and the dummy gate 17 away from the substrate 11, may be removed, or may be retained.

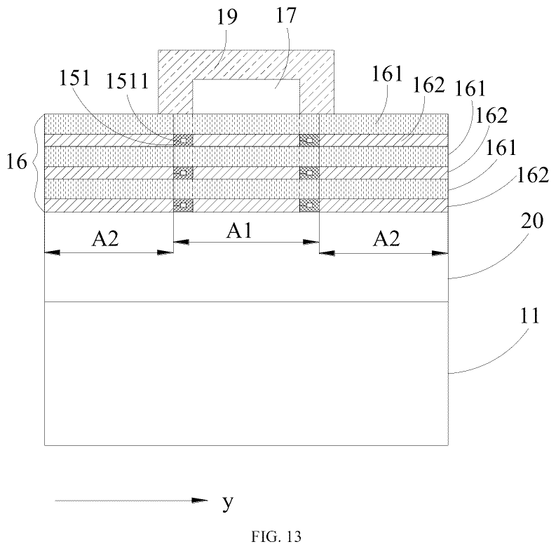

In S1200, as shown in FIG. 13, a second spacer material layer 19 is formed on the side of the stack epitaxy structure 16 and the dummy gate 17 away from the substrate 11.

Specifically, a material layer with a low dielectric constant may be deposited on the side of the stack epitaxy structure 16 and the dummy gate 17 away from the substrate 11, so as to form the second spacer material layer 19. The second spacer material layer 19 may be in direct contact with the dummy gate 17, and may be in direct contact with the gate-all-around 13 formed subsequently. Since the dielectric constant of the second spacer material layer 19 is low, the parasitic capacitance between the gate-all-around 13 and the source/drain functional portion 14 may be reduced, thereby improving the operation frequency of the circuit.

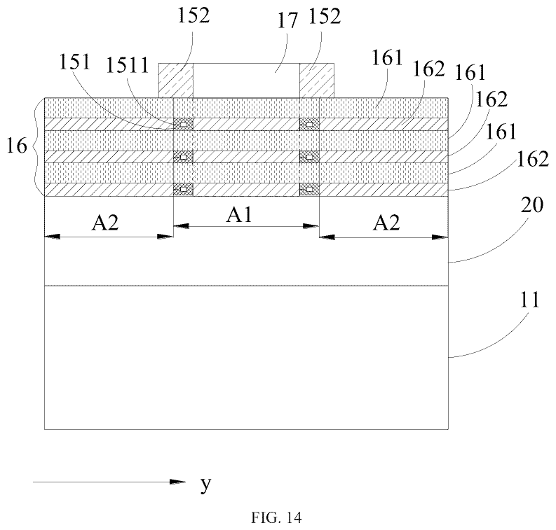

In S1400, as shown in FIG. 14, the second spacer material layer 19 is patterned to form a second spacer 152, which includes removing a portion of the second spacer material layer 19 located on the side of the dummy gate 17 away from the substrate 11 to form the second spacer 152, so as to form a spacer structure 15 including the first spacer 151 and the second spacer 152.

Specifically, a thickness of the second spacer 152 along the second direction y may be a first thickness, so that the second spacer 152 serves as a mask layer when the reserved region A2 is patterned subsequently.

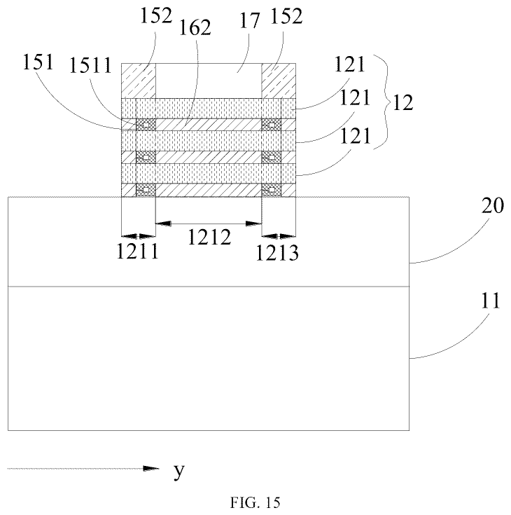

In S1600, as shown in FIG. 15, the reserved region A2 is patterned such that a size of the reserved region A2 in the second direction y is a preset size, so as to pattern the channel formation layer 161 to form a channel layer 121, thereby forming a channel layer stacking portion 12 including a plurality of channel layers 121 arranged along the thickness direction of the substrate 11. A length direction of the channel layer 121 is parallel to the second direction y. The channel layer 121 includes a first end 1211, a middle section 1212 and a second end 1213 arranged along the length direction.

Specifically, the reserved region A2 is patterned by an etching process to remove a portion of the reserved region A2 at an end of the reserved region A2 away from the thinned region A1, so as to reduce the size of the reserved region A2 in the second direction y. The reserved region A2 is patterned using an etching process such that the channel formation layer 161 is patterned to form the channel layer 121. The length direction of the channel layer 121 is parallel to the second direction y. The channel layer 121 includes the first end 1211, the middle section 1212 and the second end 1213 arranged along the length direction. The first spacer 151 is formed between first ends 1211 of adjacent channel layers 121 along the thickness direction of the substrate 11 and between second ends 1213 of the adjacent channel layers 121 along the thickness direction of the substrate 11. The sacrificial layer 162 not removed is still retained between middle sections 1212 of the adjacent channel layers 121 along the thickness direction of the substrate 11.

Specifically, the size of the reserved region A2 along the second direction y is a preset size. After the portion of the material layer which is used to form the first spacer 151 and located on the side of the stack epitaxy structure 16 and the dummy gate 17 away from the substrate 11 is removed, the above preset size may be the same as the first thickness. When the reserved region A2 is patterned, the second spacer 152 may serve as a mask.

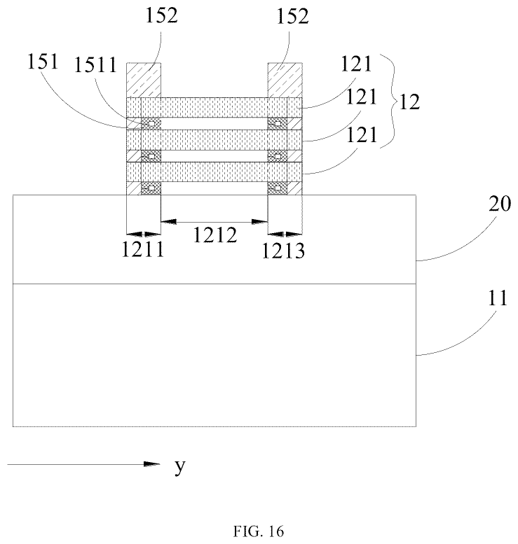

In S1800, as shown in FIG. 16, the dummy gate 17 is removed to expose a portion of the sacrificial layer 162 corresponding to the thinned region A1, and the portion of the sacrificial layer 162 corresponding to the thinned region A1 is removed.

Specifically, after the dummy gate 17 is removed, a portion of the sacrificial layer 162, which is between the middle sections 1212 of the adjacent channel layers 121 along the thickness direction of the substrate 11, is exposed. Such portion of the sacrificial layer 162 may be removed by dry etching or wet etching to leave a space for the arrangement of the gate-all-around 13, so that the gate-all-around 13 may surround the middle section 1212 with respect to the length direction of the channel layer 121.

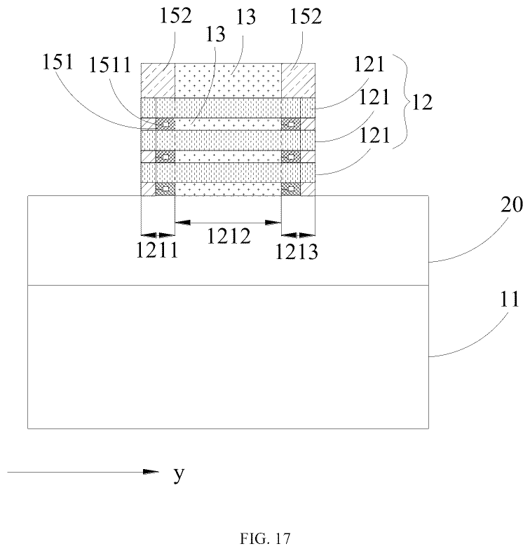

In S2000, as shown in FIG. 17, the gate-all-around 13 is formed, where the gate-all-around 13 surrounds the middle section 1212 with respect to the length direction of the channel layer 121, and the first spacer 151 is in contact with the gate-all-around 13.

Specifically, the first spacer 151 is in contact with the gate-all-around 13, and the first spacer 151 with a high dielectric constant surrounds the cavity 1511 with a low dielectric constant, so that it is possible to reduce the parasitic capacitance between the gate-all-around 13 and the subsequently formed source/drain functional portion 14. In this way, the parasitic capacitance and the driving performance may be both taken into account.

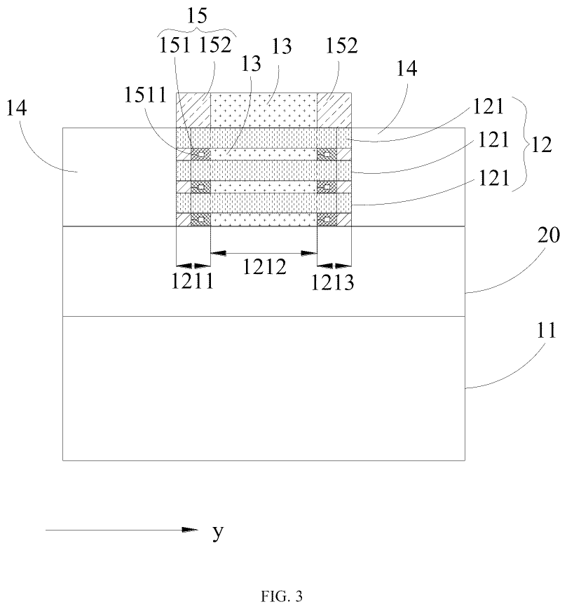

In S2200, as shown in FIG. 3, the source/drain functional portion 14 is formed. The source/drain functional portion 14 includes a source portion and a drain portion located on two opposite sides of the channel layer stacking portion 12 in the length direction, and the source/drain functional portion 14 is isolated from the gate-all-around 13 by the spacer structure 15.

In the above manufacturing method, the source/drain functional portion 14 is isolated from the gate-all-around 13 by the spacer structure 15 including the first spacer 151 and the second spacer 152. The dielectric constant of the first spacer 151 may be reduced by forming the cavity 1511 in the first spacer 151, thereby reducing the parasitic capacitance between the first spacer 151 and the gate-all-around 13 to improve the operation speed of the semiconductor device 1. In addition, the first spacer 151 is made of a material with a high dielectric constant, which may enhance the electric field coupling effect of the gate-all-around 13 on the first spacer 151, reduce the resistance of the first spacer 151 and improve the driving performance. That is, the first spacer 151, which is made of the material with a high dielectric constant, surrounds the cavity 1511 which is connected to the external air and has a low dielectric constant, so that the performance of the first spacer 151 may be comprehensively improved. In this way, the parasitic capacitance and the driving performance may be both taken into account. Furthermore, the second spacer 152 is made of the material with a low dielectric constant, which may reduce the parasitic capacitance. In the semiconductor device 1 provided in the present disclosure, the first spacer 151 made of the material with a high dielectric constant is provided to surround the cavity 1511 with a low dielectric constant, and the second spacer 152 with a low dielectric constant is provided, thereby achieving the isolation of the source/drain functional portion 14 from the gate-all-around 13, and taking into account both the parasitic capacitance and the driving performance.

Before the dummy gate 17 is formed, the above manufacturing method further includes forming a trench and a trench isolation layer 20, for isolating adjacent transistor devices. The trench is formed between adjacent channel layer stacking portions 12, and the trench isolation layer 20 is formed in the trench.

In the above manufacturing method, forming a first spacer 151 including a cavity 1511 in the hollow portion 18 includes:
forming a spacer material layer in the hollow portion 18 and on the side of the stack epitaxy structure 16 and the dummy gate 17 away from the substrate 11, so as to form the first spacer 151 including the cavity 1511 in the hollow portion 18 and form a third spacer to-be-formed portion on the side of the stack epitaxy structure 16 and the dummy gate 17 away from the substrate 11; and
patterning the third spacer to-be-formed portion to form a third spacer 153, including: removing a portion of the third spacer to-be-formed portion located on the side of the dummy gate 17 away from the substrate 11, so as to form the third spacer 153.

In the above embodiment, during the process of depositing the material layer used to form the first spacer 151, it is prone to simultaneously deposit the above-mentioned material layer used to form the first spacer 151 on the side of the stack epitaxy structure 16 and the dummy gate 17 away from the substrate 11, so as to form the third spacer to-be-formed portion on the side of the stack epitaxy structure 16 and the dummy gate 17 away from the substrate 11; and then the portion of the third spacer to-be-formed portion on the side of the dummy gate 17 away from the substrate 11 may be removed to form the third spacer 153. That is, a portion of the material layer used to form the first spacer 151, which is located on the side of the stack epitaxy structure 16 and the dummy gate 17 away from the substrate 11, is retained, so that a process of removing this portion may be omitted. Furthermore, the step of patterning the second spacer material layer 19 to form the second spacer 152 and the step of patterning the third spacer to-be-formed portion to form the third spacer 153 may be performed simultaneously, so that there is no need to add an additional process for the patterning of the third spacer to-be-formed portion, thereby simplifying the preparation process and reducing the preparation cost.

In a possible embodiment, patterning the reserved region A2 further includes:
patterning the reserved region A2 such that the size of the reserved region A2 in the second direction y is the preset size, so as to pattern the sacrificial layer 162 to form a fourth spacer 154, where the fourth spacer 154 is formed between the first spacer 151 and the source/drain functional portion 14, and the fourth spacer 154 is located between first ends 1211 of adjacent channel layers 121 and between second ends 1213 of the adjacent channel layers 121.

In the above manufacturing method, the portion of the sacrificial layer 162 in the reserved region A2 is retained and used as the fourth spacer 154. The source/drain functional portion 14 is in direct contact with the fourth spacer 154, instead of that the source/drain functional portion 14 is in direct contact with the first spacer 151. Since the crystal lattice of the material of the fourth spacer 154 is the same as or similar to the crystal lattice of the material of the source/drain functional portion 14, the direct contact between the source/drain functional portion 14 and the fourth spacer 154 may improve the dislocation problem.

Furthermore, after the dummy gate 17 is removed, the first spacer 151 may protect the portion of the sacrificial layer 162 in the reserved region A2 during the removal of the portion of the sacrificial layer 162 between the middle sections of the adjacent channel layers 121, so that an over-etching of the portion of the sacrificial layer 162 in the reserved region A2 by the etching solution may be reduced, thereby ensuring the yield of the fourth spacer 154.

The present disclosure further provides an electronic apparatus, which includes at least one semiconductor device 1 provided in the above embodiments, and/or includes at least one semiconductor device 1 manufactured by using any one of the manufacturing methods provided in the above embodiments.

In the semiconductor device 1 of the electronic apparatus, the source/drain functional portion 14 is isolated from the gate-all-around 13 by the spacer structure 15 including the first spacer 151 and the second spacer 152. The dielectric constant of the first spacer 151 may be reduced by forming the cavity 1511 in the first spacer 151, thereby reducing the parasitic capacitance between the first spacer 151 and the gate-all-around 13 to improve the operation speed of the semiconductor device 1. In addition, the first spacer 151 is made of a material with a high dielectric constant, which may enhance the electric field coupling effect of the gate-all-around 13 on the first spacer 151, reduce the resistance of the first spacer 151 and improve the driving performance. That is, the first spacer 151, which is made of the material with a high dielectric constant, surrounds the cavity 1511 which is connected to the external air and has a low dielectric constant, so that the performance of the first spacer 151 may be comprehensively improved. In this way, the parasitic capacitance and the driving performance may be both taken into account. Furthermore, the second spacer 152 is made of the material with a low dielectric constant, which may reduce the parasitic capacitance. In the semiconductor device 1 provided in the present disclosure, the first spacer 151 made of the material with a high dielectric constant is provided to surround the cavity 1511 with a low dielectric constant, and the second spacer 152 with a low dielectric constant is provided, thereby achieving the isolation of the source/drain functional portion 14 from the gate-all-around 13, and taking into account both the parasitic capacitance and the driving performance, which is conducive to improving the performance of the electronic apparatus.

The electronic apparatus provided in the present disclosure may include a secure digital card, a solid-state drive, a computing-in-memory chip, or a brain-like chip, which is not specifically limited in the present disclosure.

The above are only preferred specific implementations of the present disclosure, but the scope of protection of the present disclosure is not limited thereto. Any changes or substitutions that may be easily conceived by those skilled in the art within the technical scope disclosed in the present disclosure should fall within the scope of protection of the present disclosure. Therefore, the scope of protection of the present disclosure shall be depend on the scope of protection of the claims.

What is claimed is:

1. A semiconductor device, comprising:
a substrate;
a channel layer stacking portion formed on a side of the substrate, wherein the channel layer stacking portion comprises a plurality of channel layers arranged along a thickness direction of the substrate, a length direction of the channel layer is perpendicular to the thickness direction of the substrate, and each of the plurality of channel layers comprises a first end, a middle section and a second end arranged along the length direction of the channel layer;
a gate-all-around surrounding the middle section of the channel layer with respect to the length direction of the channel layer;
a source/drain functional portion comprising a source portion and a drain portion, wherein the source portion and the drain portion are located on two opposite sides of the channel layer stacking portion along the length direction of the channel layer; and
a spacer structure configured to isolate the source/drain functional portion from the gate-all-around, wherein the spacer structure comprises a first spacer and a second spacer, the first spacer is located between first ends of adjacent channel layers and between second ends of the adjacent channel layers, the first spacer comprises a cavity, the second spacer is located on a side of the channel layer stacking portion away from the substrate and on both sides of the gate-all-around along the length direction of the channel layer, and a dielectric constant of a material of the first spacer is greater than a dielectric constant of a material of the second spacer.

2. The semiconductor device according to claim 1, wherein the spacer structure further comprises a third spacer, the third spacer is formed between the second spacer and the gate-all-around, and a material of the third spacer is identical to the material of the first spacer.

3. The semiconductor device according to claim 1, wherein the spacer structure further comprises a fourth spacer, the fourth spacer is formed between the first spacer and the source/drain functional portion, and the fourth spacer is located between the first ends of the adjacent channel layers and between the second ends of the adjacent channel layers.

4. The semiconductor device according to claim 3, wherein an orthographic projection of the second spacer on the substrate covers an orthographic projection of the fourth spacer on the substrate.

5. The semiconductor device according to claim 1, wherein a thickness of a sidewall of the first spacer is in a range of 0.5 nm to 5 nm.

6. A method of manufacturing a semiconductor device, comprising:
providing a substrate;
forming a stack epitaxy structure on a side of the substrate, and thinning a preset region in the stack epitaxy structure on two sides along a first direction, so as to form a thinned region and a reserved region, wherein the stack epitaxy structure comprises a plurality of channel formation layers and a plurality of sacrificial layers alternately arranged in a direction away from the substrate;
forming a dummy gate covering two side surfaces of the thinned region along a second direction and covering a surface of the thinned region on a side of the thinned region away from the substrate, wherein a preset gap is formed between the dummy gate and the reserved region, and the second direction is perpendicular to each of the first direction and a thickness direction of the substrate;
removing a portion of the sacrificial layer corresponding to the preset gap to form a hollow portion;
forming a first spacer comprising a cavity in the hollow portion;
forming a second spacer material layer on a side of the stack epitaxy structure and the dummy gate away from the substrate;
patterning the second spacer material layer to form a second spacer, comprising: removing a portion of the second spacer material layer located on a side of the dummy gate away from the substrate to form the second spacer, so as to form a spacer structure comprising the first spacer and the second spacer;
patterning the reserved region such that a size of the reserved region along the second direction is a preset size, so as to pattern the channel formation layer to form a channel layer, and then form a channel layer stacking portion comprising a plurality of channel layers arranged along the thickness direction of the substrate, wherein a length direction of the channel layer is perpendicular to the thickness direction of the substrate, and each of the plurality of channel layers comprises a first end, a middle section and a second end arranged along the length direction of the channel layer;
removing the dummy gate to expose a portion of the sacrificial layer corresponding to the thinned region, and removing the portion of the sacrificial layer corresponding to the thinned region;
forming a gate-all-around surrounding the middle section of the channel layer with respect to the length direction of the channel layer, wherein the first spacer is in contact with the gate-all-around; and
forming a source/drain functional portion comprising a source portion and a drain portion, wherein the source portion and the drain portion are located on two opposite sides of the channel layer stacking portion along the length direction of the channel layer, and the source/drain functional portion is isolated from the gate-all-around by the spacer structure.

7. The method according to claim 6, wherein the forming a first spacer comprising a cavity in the hollow portion comprises:
forming a spacer material layer in the hollow portion and on the side of the stack epitaxy structure and the dummy gate away from the substrate, so as to form the first spacer comprising the cavity in the hollow portion and form a third spacer to-be-formed portion on the side of the stack epitaxy structure and the dummy gate away from the substrate; and
patterning the third spacer to-be-formed portion to form a third spacer, comprising: removing a portion of the third spacer to-be-formed portion located on the side of the dummy gate away from the substrate, so as to form the third spacer.

8. The method according to claim 7, wherein the patterning the second spacer material layer to form a second spacer and the patterning the third spacer to-be-formed portion to form a third spacer are performed simultaneously.

9. The method according to claim 6, wherein the patterning the reserved region further comprises:
patterning the reserved region such that the size of the reserved region in the second direction is the preset size, so as to pattern the sacrificial layer to form a fourth spacer, wherein the fourth spacer is formed between the first spacer and the source/drain functional portion, and the fourth spacer is located between first ends of adjacent channel layers and between second ends of the adjacent channel layers.

10. An electronic apparatus, comprising: at least one semiconductor device according to claim 1.

11. An electronic apparatus, comprising: at least one semiconductor device manufactured by using the method according to claim 6.
